(19) United States
(12) Patent Application Publication
(10) Pub. No.: US 2025/0159800 A1
(43) Pub. Date: May 15, 2025

(54) PACKAGE SUBSTRATE AND MANUFACTURING METHOD THEREOF

(71) Applicant: AaltoSemi Inc., Jiangsu (CN)

(72) Inventors: Min-Yao CHEN, Jiangsu (CN); Yin-Ju CHEN, Jiangsu (CN); Sung-Kun LIN, Jiangsu (CN); Andrew C. CHANG, Jiangsu (CN)

(21) Appl. No.: 18/934,452

(22) Filed: Nov. 1, 2024

(30) Foreign Application Priority Data
Nov. 10, 2023 (CN) 202311500824.0

(51) Int. Cl. H05K 1/02; H05K 3/46

(52) U.S. Cl. CPC H05K 1/0298; H05K 3/4644

(57) ABSTRACT

A package substrate is provided, in which a plurality of grooves are formed on a dielectric layer, so that a first circuit layer is embedded in the dielectric layer and is exposed from the grooves, wherein the depths of the plurality of grooves are uniform to facilitate embedding a plurality of solder balls in the plurality of grooves and bonding the plurality of solder balls to the first circuit layer.

### BACKGROUND

### 1. Technical Field

The present disclosure relates to a semiconductor packaging process, and more particularly, to a package substrate and a manufacturing method thereof that can improve reliability.

### 2. Description of Related Art

With the vigorous development of the electronics industry, electronic products tend to be thin, light, short and small in form, and in the direction of high performance, high functionality and high speed in terms of function. Therefore, in order to meet the high integration and miniaturization requirements of semiconductor devices, package substrates with high-density and fine-pitch circuits are often used in the packaging process.

FIG. 1A to FIG. 1F are cross-sectional schematic views illustrating a manufacturing method of a conventional package substrate 1.

As shown in FIG. 1A, a carrier 9 is provided, with a release layer 91 on a surface of a plate body 90 and a metal layer 92 formed on the release layer 91. Then, a resist layer 10 having opening areas 100 is symmetrically formed on the opposite sides of the carrier 9 so that part of the surface of the carrier 9 is exposed from the opening areas 100.

As shown in FIG. 1B, a first circuit layer 11 is formed on the metal layer 92 in the opening areas 100. Then, the resist layer 10 is removed.

As shown in FIG. 1C, a dielectric layer 12 is formed on the metal layer 92 of the carrier 9, and a plurality of blind holes 120 are formed on the dielectric layer 12.

As shown in FIG. 1D, copper is electroplated on the dielectric layer 12 and in the blind holes 120 to form a second circuit layer 13 on the dielectric layer 12, and a plurality of conductive pillars 14 electrically connecting the first circuit layer 11 and the second circuit layer 13 are formed in the blind holes 120, thereby forming a coreless circuit structure 1a.

As shown in FIG. 1E, the plate body 90 of the carrier 9 and the circuit structure 1a are separated by the release layer 91, so that the metal layer 92 is retained on the dielectric layer 12 and the first circuit layer 11.

As shown in FIG. 1F, the metal layer 92 is removed by etching, and at the same time, part of the first circuit layer 11 is removed by micro-etching to form a plurality of grooves 15 on the dielectric layer 12.

In addition, in the subsequent process, as shown in FIG. 1G, solder balls 16 electrically connected to the first circuit layer 11 can be bonded into the grooves 15, so that the package substrate 1 is connected to a semiconductor chip (not shown) or an electronic device such as a circuit board (not shown) via the solder balls 16.

However, in the conventional package substrate 1, the first circuit layers 11 and 11a are micro-etched when the metal layer 92 is removed by etching, resulting in that the depths D1, D2, D3, D4, D5 and D6 of the grooves 15 are not uniform. Therefore, it is difficult to be effectively bonded to all the solder balls 16, so that the reliability of the package substrate 1 is poor. For example, the depth D2 of the groove 15 is too shallow, making it difficult for the solder ball 16 to be embedded in the groove 15, thereby causing the solder ball 16 to fall off. Alternatively, the depth D5 of the groove 15 is too deep, making it difficult for the solder ball 16 to protrude from the groove 15, thereby causing the solder ball 16 to be unable to be soldered to a contact point of an external electronic device.

Furthermore, since the first circuit layers 11 and 11a are micro-etched when the metal layer 92 is removed by etching, side etching occurs in part of the first circuit layer 11a, causing the first circuit layer 11a to be damaged or even disconnected. Therefore, the signal transmission between the first circuit layer 11a and the solder balls 16 is poor.

In addition, since the first circuit layer 11a has the problem of being damaged by side etching, when the line width/line spacing (L/S) of the first circuit layer 21 is designed toward miniaturization, the first circuit layer 11a is more likely to be disconnected, resulting in the interruption of the signal transmission between the first circuit layer 11a and the solder balls 16. Therefore, it is impossible to mass-produce the package substrate 1 that requires miniaturization of the first circuit layers 11, 11a.

Therefore, how to overcome the various problems of the above-mentioned prior art has become an urgent issue to be solved.

### SUMMARY

In view of the various deficiencies of the prior art, the present disclosure provides a package substrate, which comprises: a dielectric layer having a first surface, a second surface opposing the first surface, and a plurality of grooves formed on the first surface, wherein depths of the plurality of grooves are uniform; a first circuit layer embedded in the first surface of the dielectric layer and exposed from the grooves; a second circuit layer formed on the second surface of the dielectric layer; and a plurality of conductive pillars formed in the dielectric layer and electrically connected to the first circuit layer and the second circuit layer.

The present disclosure also provides a method for manufacturing a package substrate, which comprises: providing a carrier having a metal layer; forming a shaping layer on part of a surface of the metal layer; forming a first circuit layer on the shaping layer; forming a dielectric layer on the metal layer and the first circuit layer, wherein the dielectric layer is defined with a first surface bonded to the metal layer and a second surface opposing the first surface; forming a second circuit layer on the second surface of the dielectric layer, wherein a plurality of conductive pillars are formed in the dielectric layer and electrically connected to the first circuit layer and the second circuit layer; removing the metal layer by etching to expose the first surface of the dielectric layer and the shaping layer, so that the shaping layer is flush with the first surface of the dielectric layer; and removing the shaping layer to form a plurality of grooves with uniform depth on the first surface of the dielectric layer, so that the first circuit layer is exposed from the grooves.

In the aforementioned manufacturing method, a material for forming the first circuit layer is different from a material for forming the shaping layer.

In the aforementioned manufacturing method, a material for forming the metal layer is different from a material for forming the shaping layer.

In the aforementioned package substrate and the manufacturing method thereof, the second circuit layer and the plurality of conductive pillars are integrally formed.

In the aforementioned package substrate and the manufacturing method thereof, a depth of each of the plurality of grooves is 0.1 micron.

In the aforementioned package substrate and the manufacturing method thereof, the method further comprises forming a plurality of solder balls in the grooves, so that the plurality of solder balls are bonded to the first circuit layer.

As can be seen from the above, the package substrate and its manufacturing method of the present disclosure mainly rely on the configuration of the shaping layer, so that the shaping layer and the first circuit layer will not be micro-etched when the metal layer is removed. Therefore, when the shaping layer is removed, the depth of the plurality of grooves can be effectively controlled so that the depths of the plurality of grooves appear uniform. Therefore, compared with the prior art, in the subsequent process of the present disclosure, the plurality of solder balls can be effectively embedded in the plurality of grooves and bonded to the first circuit layer. Therefore, the problem of the solder ball falling off or not being soldered can be avoided, thereby improving reliability.

Furthermore, via the configuration of the shaping layer, part of the material of the first circuit layer will not be removed when the shaping layer is removed, thereby effectively preventing side etching of the first circuit layer. Therefore, compared with the prior art, the present disclosure can avoid the problem of damage (such as disconnection) of the first circuit layer, thereby improving the yield of signal transmission between the first circuit layer and the solder balls.

In addition, when the line width/line spacing (L/S) of the first circuit layer is designed toward miniaturization, the first circuit layer will not be damaged (such as disconnected) due to side etching. It can effectively ensure the normal signal transmission between the first circuit layer and the solder balls. Therefore, compared with the prior art, the present disclosure is advantageous for mass production of package substrates that require miniaturization of the first circuit layer.

### BRIEF DESCRIPTION OF THE DRAWINGS

FIG. 1A to FIG. 1F are cross-sectional schematic views illustrating a manufacturing method of a conventional package substrate.

FIG. 1G is a schematic cross-sectional view of the subsequent process of FIG. 1F.

FIG. 2A to FIG. 2G are schematic cross-sectional views illustrating a manufacturing method of a package substrate according to the present disclosure.

FIG. 2H is a schematic cross-sectional view of the subsequent process of FIG. 2G.

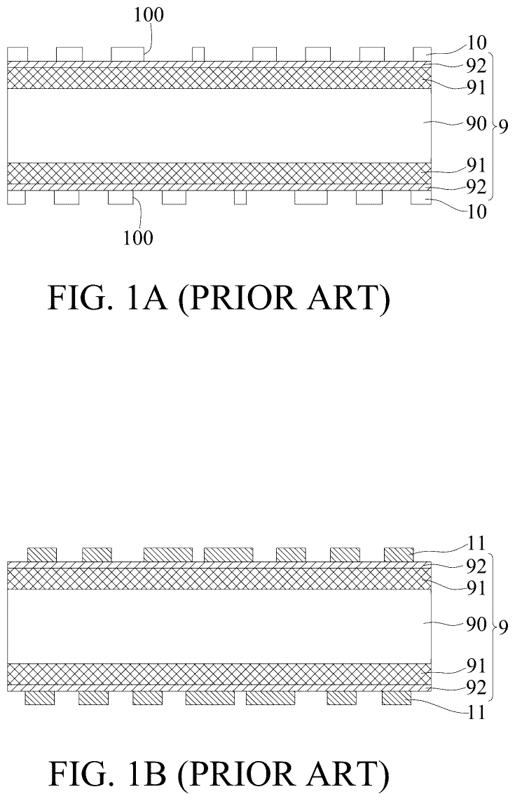

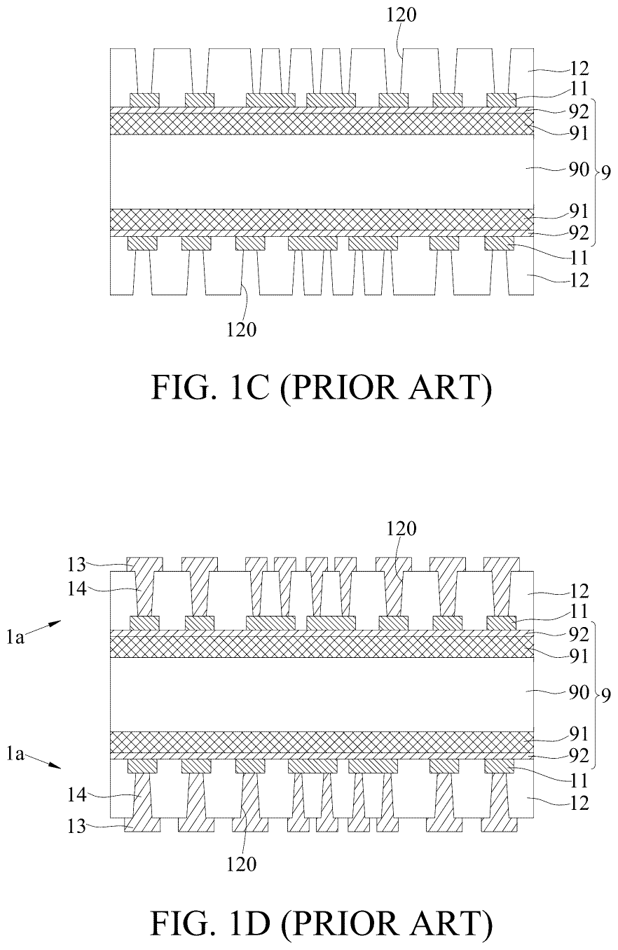

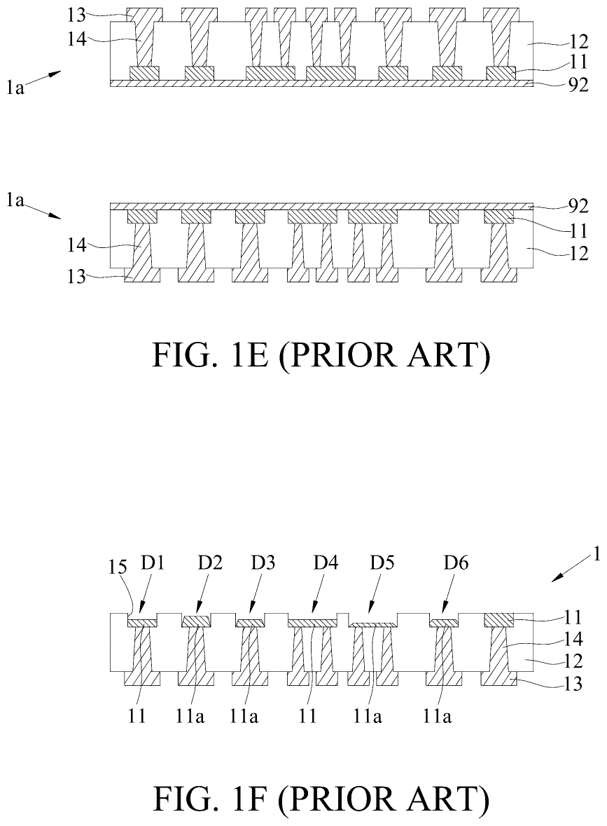

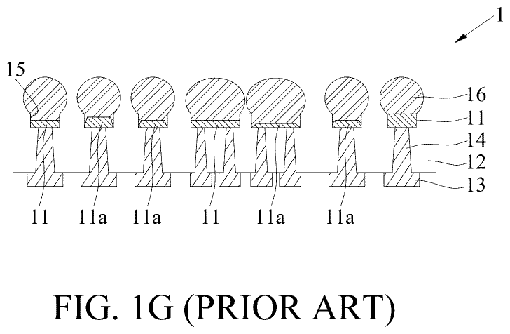

### DETAILED DESCRIPTIONS

Embodiments of the present disclosure are described below with specific examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

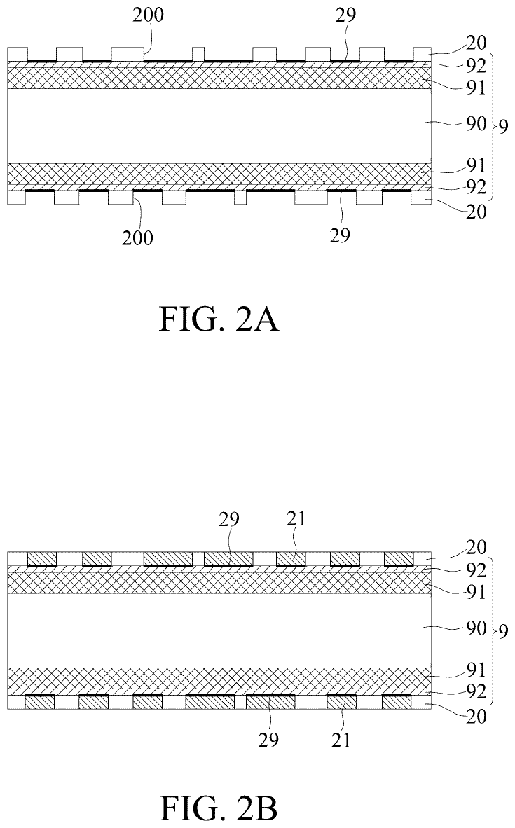

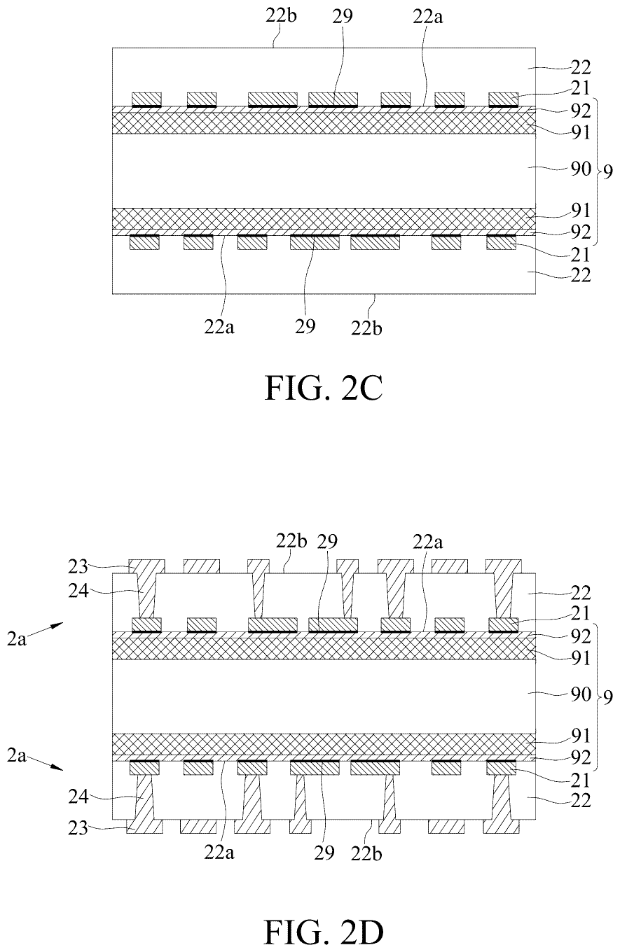

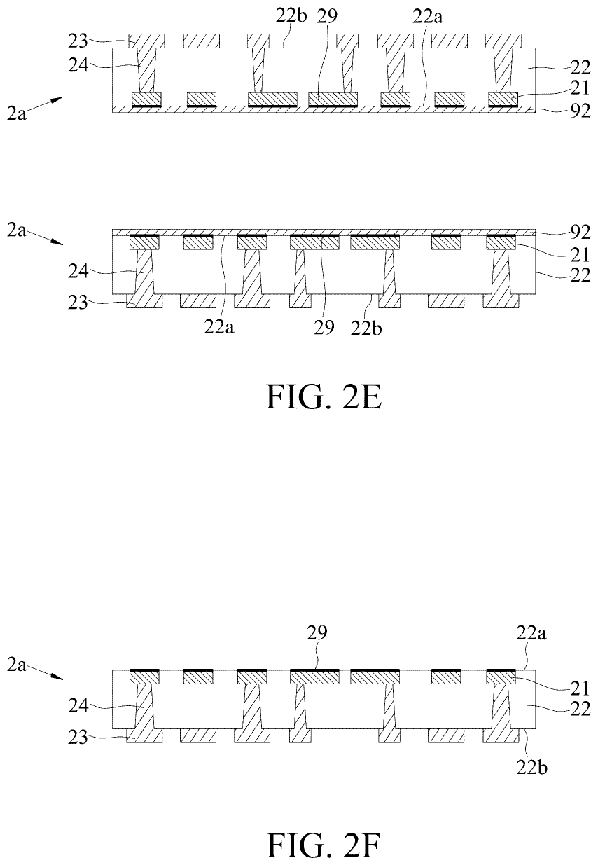

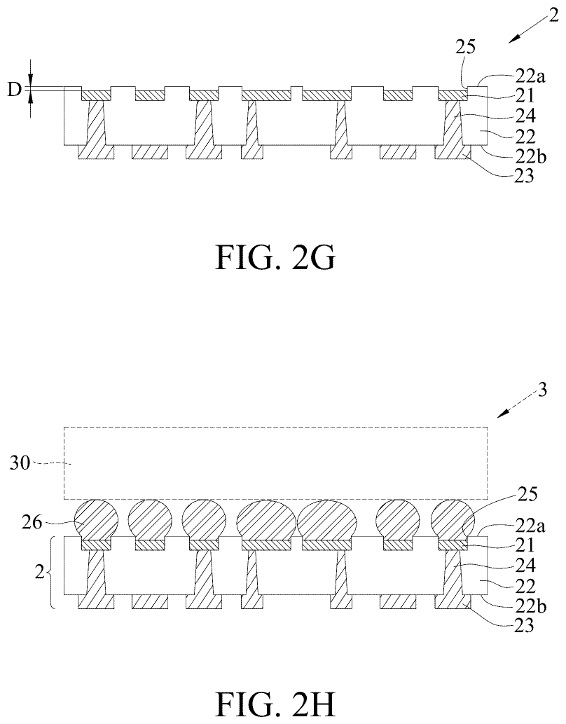

FIG. 2A to FIG. 2G are schematic cross-sectional views illustrating a manufacturing method of a package substrate 2 according to the present disclosure.

As shown in FIG. 2A, a carrier 9 is provided, and a resist layer 20 having opening areas 200 is symmetrically formed on opposite sides of the carrier 9. Therefore, part a surface of the carrier 9 is exposed from the opening areas 200, and a shaping layer 29 is formed on the surface of the carrier 9 in the opening areas 200.

In one embodiment, the carrier 9 is a temporary carrier board, which can be a plate with metal layers on opposite sides, such as a copper foil substrate. A surface of a plate body 90 of the carrier 9 is provided with a release layer 91, and a metal layer 92 such as a copper layer is formed on the release layer 91, so that the shaping layer 29 is formed on the metal layer 92.

Furthermore, the resist layer 20 is a dry film, and the shaping layer 29 is used as a seed layer, which includes a metal material, such as a nickel layer, so that the material for forming the shaping layer 29 is different from the material for forming the metal layer 92. For example, the shaping layer 29 can be formed by sputtering, E-less coating or other methods.

As shown in FIG. 2B, a patterned wiring process is performed via the metal layer 92 to form a first circuit layer 21 on the shaping layer 29. In addition, the pattern layout of the shaping layer 29 is at least or entirely corresponding to the pattern layout of the first circuit layer 21.

In one embodiment, the first circuit layer 21 is made of copper, and its formation material is the same as the material for forming the metal layer 92, so that the material for forming the first circuit layer 21 is different from the material for forming the shaping layer 29. For example, the first circuit layer 21 adopts a redistribution layer (RDL) specification.

As shown in FIG. 2C, the resist layer 20 is removed. Next, a dielectric layer 22 is formed on the metal layer 92 of the carrier 9, and the dielectric layer 22 is defined with a first surface 22a and a second surface 22b opposing the first surface 22a, so that the first surface 22a of the dielectric layer 22 is bonded to the metal layer 92.

In one embodiment, the dielectric layer 22 is made of ajinomoto build-up film (ABF), polybenzoxazole (PBO), polyimide (PI), prepreg with glass fiber (PP) or other dielectric materials.

As shown in FIG. 2D, a second circuit layer 23 is formed on the second surface 22b of the dielectric layer 22, and a plurality of conductive pillars 24 electrically connecting the first circuit layer 21 and the second circuit layer 23 are formed in the dielectric layer 22. As such, a coreless circuit structure 2a is formed.

In one embodiment, the second circuit layer 23 is produced by electroplating metal (such as copper) or other methods using a build-up process. For example, a plurality of blind holes are first formed on the second surface 22b of the dielectric layer 22 by laser, and then copper is electroplated on the dielectric layer 22 and in the blind holes, so as to integrally form the second circuit layer 23 and the conductive pillars 24.

Furthermore, the second circuit layer 23 is made of copper material. For example, the second circuit layer 23 adopts a redistribution layer (RDL) specification.

It should be understood that by using the build-up process, the number of dielectric layers in the circuit structure 2a can be designed as required to produce the required number of second circuit layers 23.

As shown in FIG. 2E, the plate body 90 of the carrier 9 and the circuit structure 2a are separated by the release layer 91, so that the metal layer 92 is retained on the first surface 22a of the dielectric layer 22 and the shaping layer 29.

In one embodiment, the release layer 91 is removed by peeling off or other methods to separate the plate body 90 and the metal layer 92.

As shown in FIG. 2F, the metal layer 92 is removed by etching to expose the first surface 22a of the dielectric layer 22 and the shaping layer 29, so that the shaping layer 29 is flush with the first surface 22a of the dielectric layer 22.

As shown in FIG. 2G, the shaping layer 29 is removed to form a plurality of grooves 25 with the same depth D on the first surface 22a of the dielectric layer 22, so that the first circuit layer 21 is exposed from the grooves 25.

In one embodiment, etching is used to remove the shaping layer 29, so that the depth D of each of the plurality of grooves 25 is 0.1 micron (um).

In addition, in the subsequent process, as shown in FIG. 2H, solder balls 26 electrically connected to the first circuit layer 21 can be bonded into the grooves 25, so that the package substrate 2 is connected to an electronic device 30 such as a semiconductor chip, a passive element, a silicon interposer, a circuit board or other elements via the solder balls 26 to form an electronic package 3.

Therefore, the manufacturing method of the present disclosure mainly forms a shaping layer 29 whose material is different from the first circuit layer 21 and the metal layer 92 between the metal layer 92 and the first circuit layer 21, so that the shaping layer 29 and the first circuit layer 21 will not be etched when removing the metal layer 92. Therefore, when the shaping layer 29 is removed, part of the first circuit layer 21 will not be removed, so that the depths D of the plurality of grooves 25 are effectively controlled to be uniform, resulting in that the plurality of solder balls 26 can be effectively embedded in the plurality of grooves 25 to be bonded to the first circuit layer 21 and can protrude from the grooves 25. Accordingly, the problem of the solder balls 26 falling off or the electronic device 30 not being soldered can be avoided.

Furthermore, since the material for forming the first circuit layer 21 is different from the material for forming the shaping layer 29, part of the material of the first circuit layer 21 will not be removed when the shaping layer 29 is removed, so as to effectively prevent lateral etching of the first circuit layer 21. Therefore, the problem of damage (such as disconnection) can be avoided, and the problem of poor signal transmission between the first circuit layer 21 and the solder balls 26 can be avoided.

In addition, when the line width/line spacing (L/S) of the first circuit layer 21 is designed toward miniaturization, the first circuit layer 21 will not be damaged (such as disconnected) due to side etching, thereby ensuring normal signal transmission between the first circuit layer 21 and the solder balls 26. Therefore, the manufacturing method of the present disclosure is conducive to mass production of the package substrate 2 that requires the miniaturization of the first circuit layer 21 via the shaping layer 29.

The present disclosure also provides a package substrate 2, which comprises: at least one dielectric layer 22, a first circuit layer 21, at least one second circuit layer 23, and a plurality of conductive pillars 24.

The dielectric layer 22 has a first surface 22a, a second surface 22b opposing the first surface 22a, and a plurality of grooves 25 formed on the first surface 22a, wherein the depths D of the plurality of grooves 25 are uniform.

The first circuit layer 21 is embedded in the first surface 22a of the dielectric layer 22 and is exposed from the grooves 25.

The second circuit layer 23 is formed on the second surface 22b of the dielectric layer 22.

The conductive pillars 24 are formed in the dielectric layer 22 and electrically connect the first circuit layer 21 and the second circuit layer 23.

In one embodiment, the depth D of each of the plurality of grooves 25 is 0.1 micron.

In one embodiment, the second circuit layer 23 and the plurality of conductive pillars 24 are integrally formed.

In one embodiment, the package substrate 2 further comprises a plurality of solder balls 26 formed in the grooves 25 to be bonded to the first circuit layer 21.

To sum up, the package substrate and its manufacturing method of the present disclosure effectively control the depth of the plurality of grooves to be uniform via the configuration of the shaping layer, so that the plurality of solder balls can be effectively embedded in the plurality of grooves and bonded to the first circuit layer. Therefore, the problem of the solder ball falling off or not being soldered can be avoided, so the present disclosure can improve reliability.

Furthermore, via the configuration of the shaping layer, part of the material of the first circuit layer will not be removed when the shaping layer is removed, thereby effectively preventing side etching of the first circuit layer. Therefore, the present disclosure can avoid the problem of damage (such as disconnection) of the first circuit layer and improve the yield of signal transmission between the first circuit layer and the solder balls.

In addition, when the line width/line spacing (L/S) of the first circuit layer is designed toward miniaturization, the first circuit layer will not be damaged (such as disconnected) due to side etching, so as to effectively ensure the normal signal transmission between the first circuit layer and the solder balls. Therefore, the present disclosure is beneficial to mass production of package substrates that require miniaturization of the first circuit layer.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A package substrate, comprising:
a dielectric layer having a first surface, a second surface opposing the first surface, and a plurality of grooves formed on the first surface, wherein depths of the plurality of grooves are uniform;
a first circuit layer embedded in the first surface of the dielectric layer and exposed from the grooves;
a second circuit layer formed on the second surface of the dielectric layer; and
a plurality of conductive pillars formed in the dielectric layer and electrically connected to the first circuit layer and the second circuit layer.

2. The package substrate of claim 1, wherein a depth of each of the plurality of grooves is 0.1 micron.

3. The package substrate of claim 1, wherein the second circuit layer and the plurality of conductive pillars are integrally formed.

4. The package substrate of claim 1, further comprising a plurality of solder balls formed in the grooves to be bonded to the first circuit layer.

5. A method for manufacturing a package substrate, comprising:
providing a carrier having a metal layer;
forming a shaping layer on part of a surface of the metal layer;
forming a first circuit layer on the shaping layer;
forming a dielectric layer on the metal layer and the first circuit layer, wherein the dielectric layer is defined with a first surface bonded to the metal layer and a second surface opposing the first surface;
forming a second circuit layer on the second surface of the dielectric layer, wherein a plurality of conductive pillars are formed in the dielectric layer and electrically connected to the first circuit layer and the second circuit layer;
removing the metal layer by etching to expose the first surface of the dielectric layer and the shaping layer, so that the shaping layer is flush with the first surface of the dielectric layer; and
removing the shaping layer to form a plurality of grooves with uniform depth on the first surface of the dielectric layer, so that the first circuit layer is exposed from the grooves.

6. The method of claim 5, wherein a material for forming the first circuit layer is different from a material for forming the shaping layer.

7. The method of claim 5, wherein a material for forming the metal layer is different from a material for forming the shaping layer.

8. The method of claim 5, wherein the second circuit layer and the plurality of conductive pillars are integrally formed.

9. The method of claim 5, wherein a depth of each of the plurality of grooves is 0.1 micron.

10. The method of claim 5, further comprising forming a plurality of solder balls in the grooves, so that the plurality of solder balls are bonded to the first circuit layer.
